(19) United States
(12) Patent Application Publication
(10) Pub. No.: US 2026/0102776 A1
(43) Pub. Date: Apr. 16, 2026

(54) TRANSFER MODULE AND SEMICONDUCTOR MANUFACTURING EQUIPMENT INCLUDING THE SAME

(71) Applicant: SEMES CO., LTD., Cheonan-si (KR)

(72) Inventors: Chan Young CHOI, Cheonan-si (KR); Sang Hoon KIM, Cheonan-si (KR); Cheol Yong SHIN, Cheonan-si (KR); Sun Wook JUNG, Cheonan-si (KR); Cheng Bin CUI, Cheonan-si (KR); Hyung Bin IM, Cheonan-si (KR)

(73) Assignee: SEMES CO., LTD., Cheonan-si (KR)

(21) Appl. No.: 19/264,997

(22) Filed: Jul. 10, 2025

(30) Foreign Application Priority Data
Oct. 11, 2024 (KR) 10-2024-0138619

(51) Int. Cl. B03C 7/02; H01L 21/677

(52) U.S. Cl. CPC B03C 7/023; H10P 72/3202

(57) ABSTRACT

Disclosed are a transfer module capable of effectively discharging very fine particles present on a wall surface or a bottom surface and semiconductor manufacturing equipment including the transfer module. The transfer module configured to transfer a substrate in the semiconductor manufacturing equipment includes a frame body, a track disposed on the frame body, a transfer robot configured to travel along the track, and a particle collection device provided in the frame body. The particle collection device includes a stacked substrate in which three-phase electrodes are disposed to be spaced apart from each other in a horizontal direction and a vertical direction and a three-phase power supply configured to supply three-phase power to the three-phase electrodes.

### CROSS-REFERENCE TO THE RELATED APPLICATION

The present application claims priority to and the benefit of Korean Patent Application No. 10-2024-0138619, filed on Oct. 11, 2024, in the Korean Intellectual Property Office, the entire disclosure of which is incorporated herein by reference.

### BACKGROUND

### 1. Field

The present disclosure relates to a transfer module configured to transfer a substrate and semiconductor manufacturing equipment including the same.

### 2. Description of the Related Art

A semiconductor (or display) manufacturing process is a process for manufacturing a semiconductor device on a substrate (e.g., a wafer), and includes, for example, exposure, deposition, etching, ion implantation, and cleaning. In order to perform each manufacturing process, semiconductor manufacturing equipment that performs each process is provided in a clean room of a semiconductor manufacturing plant, and process treatment is performed on a substrate loaded in the semiconductor manufacturing equipment.

A transfer module configured to transfer a substrate is provided between modules in semiconductor manufacturing equipment. The transfer module includes mechanisms that move along a plurality of driving axes. During operation of the transfer module, fine particles are continuously generated. Such particles may not only interfere with the operation of the transfer module but also contaminate the substrate.

An exhaust fan is mounted in the transfer module in order to discharge particles to the outside. However, if very fine particles are present on a wall surface or a bottom surface, it is difficult to discharge the particles through airflow.

### SUMMARY

The present disclosure provides a transfer module capable of effectively discharging very fine particles present on a wall surface or a bottom surface and semiconductor manufacturing equipment including the transfer module.

A transfer module configured to transfer a substrate in semiconductor manufacturing equipment according to the present disclosure includes a frame body, a track disposed on the frame body, a transfer robot configured to travel along the track, and a particle collection device provided in the frame body. The particle collection device includes a stacked substrate in which three-phase electrodes are disposed to be spaced apart from each other in a horizontal direction and a vertical direction and a three-phase power supply configured to supply three-phase power to the three-phase electrodes.

According to an embodiment of the present disclosure, the frame body may include a column supporting a lower portion of the track, a base frame supporting a lower portion of the column, and a base plate mounted at a central portion of the base frame and including a plurality of first through-holes connected to an exhaust fan configured to generate a negative pressure.

According to an embodiment of the present disclosure, the stacked substrate may be disposed on the base plate and may include a plurality of second through-holes formed in alignment with the plurality of first through-holes.

According to an embodiment of the present disclosure, the three-phase power supply may include a first phase power supply configured to apply a first phase sinusoidal voltage to a first phase electrode among the three-phase electrodes, a second phase power supply configured to apply a second phase sinusoidal voltage, having a phase difference of 120 degrees from the first phase sinusoidal voltage, to a second phase electrode among the three-phase electrodes, and a third phase power supply configured to apply a third phase sinusoidal voltage, having a phase difference of −120 degrees from the first phase sinusoidal voltage, to a third phase electrode among the three-phase electrodes.

According to an embodiment of the present disclosure, the stacked substrate may include a first coating layer, a first electrode layer disposed under the first coating layer and electrically connected to the three-phase power supply, a first adhesive layer disposed under the first electrode layer, a second electrode layer disposed under the first adhesive layer and electrically connected to the three-phase power supply, an inner layer material disposed under the second electrode layer, a third electrode layer disposed under the inner layer material and electrically connected to the three-phase power supply, a second adhesive layer disposed under the third electrode layer, a ground electrode layer disposed under the second adhesive layer, and a second coating layer disposed under the ground electrode layer.

According to an embodiment of the present disclosure, the stacked substrate may further include a first ground electrode embedded in the first adhesive layer and a second ground electrode embedded in the inner layer material.

According to an embodiment of the present disclosure, three-phase electrodes connected to the three-phase power supply and ground electrodes connected to a ground may be alternately arranged in a horizontal direction in the first electrode layer.

According to an embodiment of the present disclosure, in the first electrode layer, a first three-phase electrode, a second three-phase electrode, and a third three-phase electrode may be arranged at regular intervals, with the ground electrodes interposed therebetween.

According to an embodiment of the present disclosure, the three-phase electrodes may be alternately arranged in a first horizontal direction, which is a traveling direction of the transfer robot.

According to an embodiment of the present disclosure, the three-phase electrodes may be alternately arranged in a second horizontal direction perpendicular to a first horizontal direction, which is a traveling direction of the transfer robot.

According to an embodiment of the present disclosure, the particle collection device may include a stacked substrate in which three-phase electrodes are disposed to be spaced apart from each other in a horizontal direction and a three-phase power supply configured to supply three-phase power to the three-phase electrodes.

Semiconductor manufacturing equipment according to the present disclosure includes a load port module including a placing table configured to allow a cassette accommodating a substrate to be placed thereon, an index module including an index robot configured to transfer the substrate with respect to the cassette, a transfer module configured to receive the substrate from the index module and to transfer the substrate to one or more process chambers configured to perform processing on the substrate, and a processing module having the one or more process chambers arranged therein.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 shows a layout of semiconductor manufacturing equipment according to the present disclosure;

FIG. 2 shows an example of a transfer module including a contact-driven transfer robot;

FIGS. 3A and 3B show cross-sections of the transfer module, taken along a Y-Z plane and an X-Z plane in FIG. 2;

FIGS. 4A and 4B shows an example of the transfer module including a transfer robot that operates in a non-contact manner;

FIGS. 5 and 6 show an example of the cross-section of a stacked substrate having multiple electrode layers;

FIG. 7 shows an example of the cross-section of the stacked substrate in which a plurality of ground electrodes is embedded;

FIG. 8 shows an example of a wiring structure in an electrode layer of the stacked substrate;

FIGS. 9 and 10 show another example of a stacked substrate having a single electrode layer;

FIG. 11 shows a case in which three-phase electrodes are alternately arranged in the traveling direction of the transfer robot; and

FIG. 12 shows a case in which the three-phase electrodes are alternately arranged in a direction perpendicular to the traveling direction of the transfer robot.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween. In addition, throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

Semiconductor manufacturing equipment according to an embodiment may be used to perform processing on a substrate such as a semiconductor wafer (or a flat display panel). In particular, the semiconductor manufacturing equipment 1 of the present disclosure may be an apparatus that performs liquid processing (e.g., cleaning, developing, or coating) or plasma processing (e.g., dry etching or deposition) on the substrate.

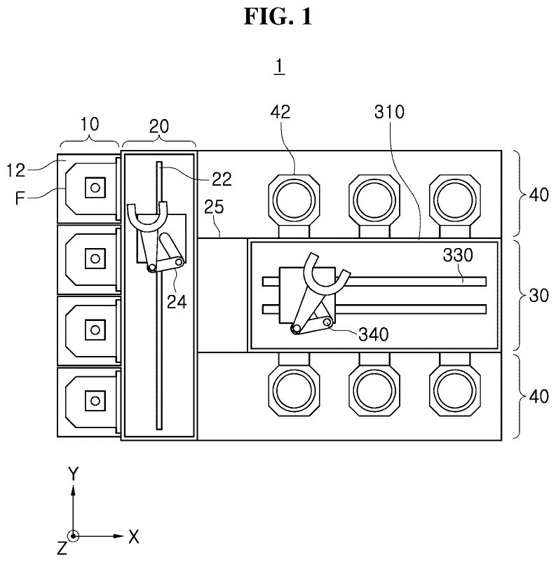

FIG. 1 shows a layout of semiconductor manufacturing equipment according to the present disclosure. The semiconductor manufacturing equipment 1 is configured to perform processing on a substrate loaded therein and to discharge the processed substrate. The semiconductor manufacturing equipment 1 includes a load port module 10, an index module 20, a transfer module 30, and a processing module 40. The semiconductor manufacturing equipment 1 may have a shape elongated in a first horizontal direction X. In this specification, the first horizontal direction X is a direction in which the transfer module 30 extends and a transfer robot 340 travels. A second horizontal direction Y is a direction perpendicular to the first horizontal direction X. A vertical direction Z is a direction perpendicular to both the first horizontal direction X and the second horizontal direction Y.

The load port module 10 is disposed at one side of the semiconductor manufacturing equipment 1 and is exposed to be accessible from the outside. As shown in FIG. 1, in the semiconductor manufacturing equipment 1, the load port module 10 includes a placing table 12 on which a cassette F accommodating a substrate is placed. The placing table 12 may be provided in plural, and the plurality of placing tables 12 may be disposed in the second horizontal direction Y. For example, four placing tables 12 may be disposed in the second horizontal direction Y. The cassette F is a container configured to accommodate a substrate. A plurality of substrates may be accommodated in each cassette F. The cassette F may be a front opening unified pod (FOUP) having an openable side. When the cassette F is placed on the placing table 12, a door of the cassette F may be opened by an opener (not shown) of the load port module 10, so that the substrate may be unloaded. In addition, a processed substrate may be loaded in the cassette F.

The index module 20 is disposed between the load port module 10 and the transfer module 30 in the semiconductor manufacturing equipment 1. The index module 20 may unload a substrate from the cassette F located at the load port module 10 and may deliver the substrate to the transfer module 30. In addition, the index module 20 may receive a substrate from the transfer module 30 and may load the substrate into the cassette F. The index module 20 includes an index rail 22 extending in the second horizontal direction Y and an index robot 24 configured to be movable along the index rail 22. The index robot 24 may move along the index rail 22 to unload a substrate from the cassette F and deliver the substrate to the transfer module 30. In addition, the index robot 24 may receive a substrate from the transfer module 30 and may load the substrate into the cassette F.

A buffer 25 configured to temporarily store a substrate may be disposed between the index module 20 and the transfer module 30. A space for accommodating a substrate is defined in the buffer 25. When the interiors of the transfer module 30 and the processing module 40 are maintained under vacuum, the buffer 25 may receive a substrate from the index module 20, and the interior of the buffer 25 may be switched from atmospheric pressure to vacuum. In the vacuum state, the substrate is delivered from the buffer 25 to the transfer module 30. The buffer 25 may be referred to as a load lock chamber. The buffer 25 may be omitted.

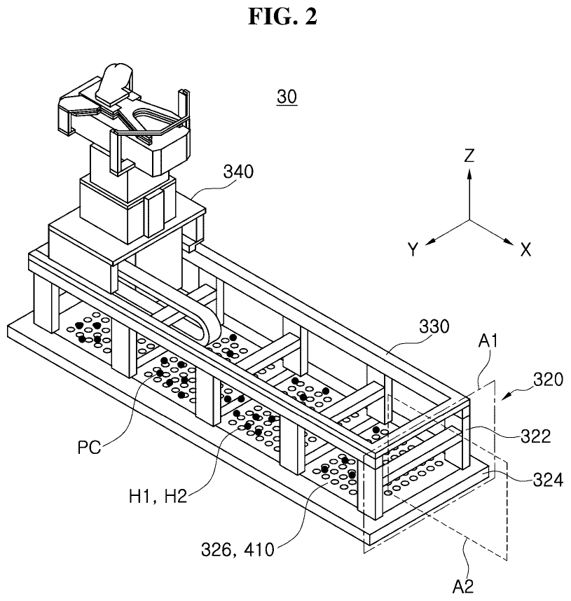

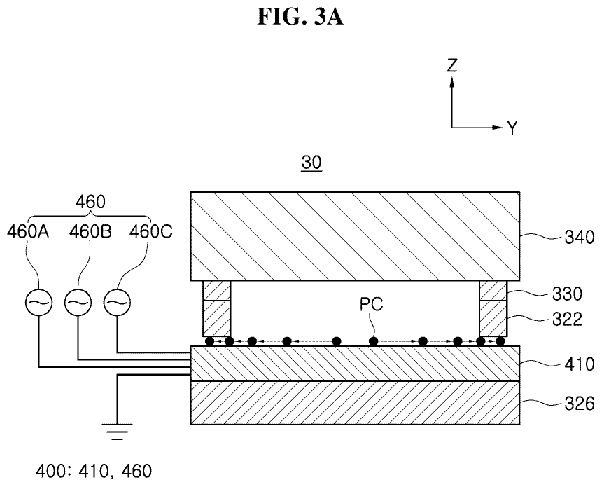

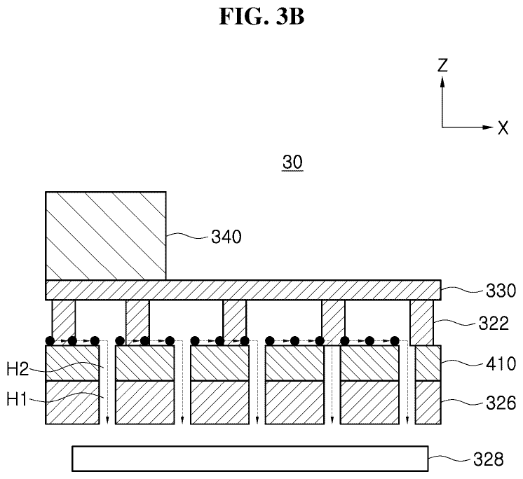

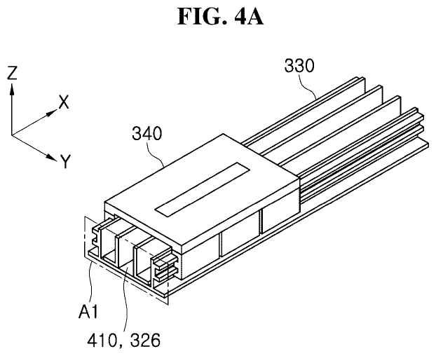

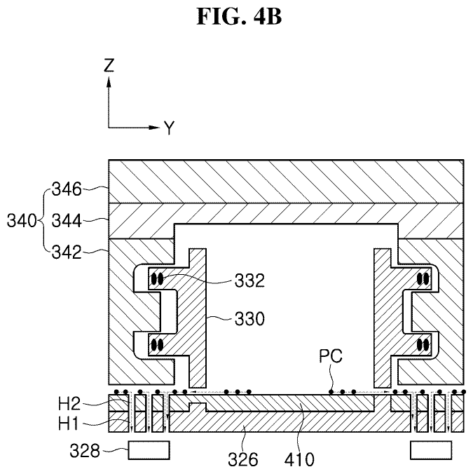

The transfer module 30 may receive a substrate from the index module 20 and may transfer the substrate to a process chamber 42 configured to perform processing on the substrate. In addition, the transfer module 30 may pick up a processed substrate from the process chamber 42 and may deliver the substrate to the index module 20. The transfer module 30 may extend in the first horizontal direction X. The process chamber 42 may be provided in plural, and the plurality of process chambers 42 may be disposed on both sides of the transfer module 30. The transfer module 30 is disposed in a transfer chamber 310. The transfer chamber 310 defines a space for mounting the transfer module 30 between the index module 20 and the processing module 40. The transfer module 30 and an exhaust fan 328 (see FIGS. 3B and 4) configured to discharge air from the transfer module 30 to the outside may be disposed in the transfer chamber 310. In addition, the transfer chamber 310 may include an electrical mechanism for operation of the transfer module 30. An exhaust fan may also be mounted to a top of the transfer chamber 310, and an exhaust structure for discharging airflow may be mounted on a bottom surface of the transfer chamber 310. A track 330 and a transfer robot 340 configured to move along the track 330 are disposed in the transfer chamber 310. A detailed structure of the transfer module 30 will be described later with reference to FIGS. 2 to 4.

The processing module 40 includes one or more process chambers 42 arranged therein. The processing module 40 may include process chambers arranged in the first horizontal direction X. In addition, the process chambers may be stacked in two or more tiers in the vertical direction Z. FIG. 1 shows an example in which three process chambers 42 are disposed on each of opposite sides with respect to the first horizontal direction. When a substrate is loaded into each process chamber 42, processing is performed on the substrate. The processed substrate may be unloaded to the outside by the transfer module 30.

FIG. 2 shows an example of the transfer module 30 including a contact-driven transfer robot 340. Referring to FIG. 2, the transfer robot 340 moves along the track 330 using a contact-based mechanism such as wheels. The transfer module 30 according to the present disclosure may include a frame body 320, a track 330, a transfer robot 340, and a particle collection device 400.

The frame body 320 is a structure to which the track 330 may be mounted. The frame body 320 is mounted on the bottom of the transfer chamber 310 shown in FIG. 1. Referring to FIG. 2, the frame body 320 includes columns 322 that support the lower portion of the track 330. The frame body 320 includes a base frame 324 that supports the lower portions of the columns 322. The frame body 320 includes a base plate 326 that is mounted at a central portion of the base frame 324. The base plate 326 includes a plurality of first through-holes H1 connected to an exhaust fan 328 (see FIG. 3B) that generates a negative pressure.

The track 330 is disposed on the frame body 320. The track 330 may be supported by the columns 322 of the frame body 320. The track 330 defines a travel path of the transfer robot 340. The track 330 may be elongated in the first horizontal direction X. A rail on which the transfer robot 340 travels and a power supply line for supply of power to the transfer robot 340 may be mounted to the track 330.

The transfer robot 340 transfers a substrate while traveling along the track. The transfer robot 340 includes a traveling unit that travels along the track. The transfer robot 340 may include a robot arm and a robot hand coupled to the traveling unit. The robot arm has a plurality of driving axes and is configured to move the robot hand in a desired direction. The robot hand is configured to support a lower portion of the substrate.

The particle collection device 400 is configured to remove particles present in the transfer module 30. The particle collection device 400 is configured to effectively remove particles present on the underlying base plate 326 using dielectrophoretic force and electrostatic force, which will be described later.

FIG. 3A schematically shows a cross-section of the transfer module 30, taken along a Y-Z plane A1 in FIG. 2, and FIG. 3B schematically shows a cross-section of the transfer module 30, taken along an X-Z plane A2 in FIG. 2. FIGS. 3A and 3B show a state in which a stacked substrate 410 is disposed on the base plate 326 in the transfer module 30 and a three-phase power supply 460 is electrically connected to the stacked substrate 410.

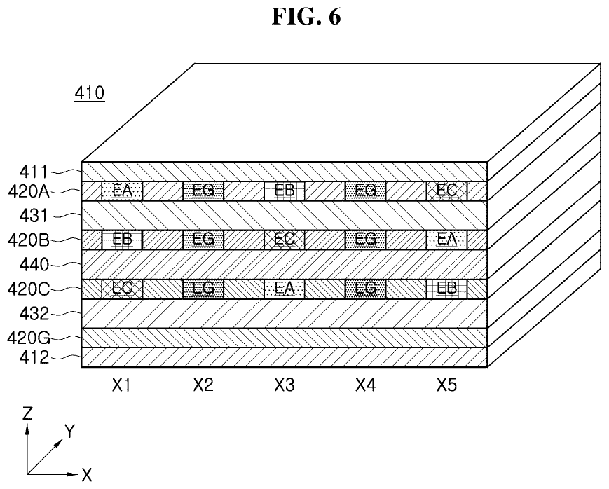

Referring to FIGS. 3A and 3B, a particle collection device 400 configured to remove particles present on the base plate 326 is provided. The particle collection device 400 includes a stacked substrate 410 and a three-phase power supply 460. In the stacked substrate 410, three-phase electrodes EA, EB, and EC are disposed to be spaced apart from each other in the vertical direction Z and the horizontal direction X or Y. Alternatively, in the stacked substrate 410, the three-phase electrodes EA, EB, and EC are disposed to be spaced apart from each other in the horizontal directions X and Y (see FIG. 6). The three-phase power supply 460 supplies three-phase power to the three-phase electrodes EA, EB, and EC of the stacked substrate 410. The stacked substrate 410 is disposed on the base plate 326. The stacked substrate 410 includes second through-holes H2 formed in alignment with the first through-holes H1. That is, the first through-holes H1 and the second through-holes H2 may be disposed at the same position and may be formed to have the same size and shape. Alternatively, the second through-holes H2 may differ in size or shape from the first through-holes H1.

In the present disclosure, a three-phase circuit supplies power using three phases. Each phase has a phase difference of 120 degrees from the others. This 120-degree phase difference allows constant and balanced supply of power.

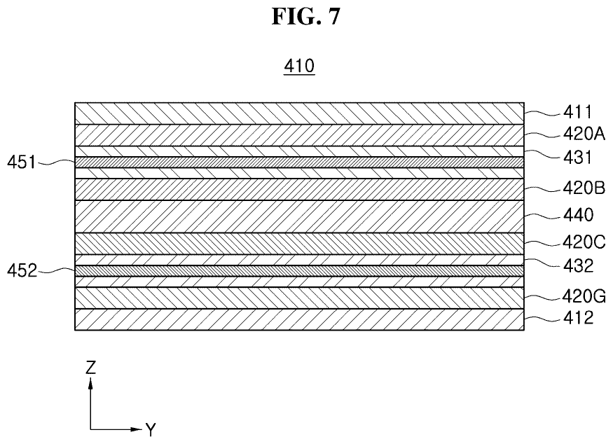

The three-phase power supply 460 supplies alternating current power with three different phases. The three-phase power supply 460 includes a first phase power supply 460A, a second phase power supply 460B, and a third phase power supply 460C. The first phase power supply 460A applies a first phase sinusoidal voltage to a first phase electrode EA among the three-phase electrodes (see FIG. 7). The second phase power supply 460B applies a second phase sinusoidal voltage, which has a phase difference of 120 degrees from the first phase sinusoidal voltage, to a second phase electrode EB among the three-phase electrodes (see FIG. 7). The third phase power supply 460C applies a third phase sinusoidal voltage, which has a phase difference of −120 degrees from the first phase sinusoidal voltage, to a third phase electrode EC among the three-phase electrodes (see FIG. 7). That is, the first phase power supply 460A, the second phase power supply 460B, and the third phase power supply 460C may apply voltages, which have phase differences of 120 degrees from each other, to the three-phase electrodes.

Referring to FIGS. 3A and 3B, the stacked substrate 410 of the particle collection device 400 is disposed on the base plate 326. The substrate transfer robot 340 is configured to move along the track 330. The track 330 is supported by the columns 322. The transfer robot 340 is configured to move in the first horizontal direction X. An exhaust fan 328 is disposed below the base plate 326. A negative pressure is formed in the first through-holes H1 and the second through-holes H2 by the exhaust fan 328. Particles PC may be discharged to the outside through the first through-holes H1 and the second through-holes H2.

The particle collection device 400 applies an alternating current voltage or a three-phase voltage to the stacked substrate 410 disposed on the base plate 326 to generate dielectrophoretic force and electrostatic force. In general, because particles PC attached to a bottom surface or a wall surface do not move effectively through airflow, they may be difficult to discharge. However, the dielectrophoretic force and the electrostatic force generated by the particle collection device 400 may guide the particles PC to the first through-holes H1 and the second through-holes H2.

FIGS. 4A and 4B shows examples of the transfer module including a transfer robot 340 that operates in a non-contact manner. FIG. 4A shows a perspective view of the transfer module including a transfer robot 340. FIG. 4B shows a cross-sectional view of the transfer module including a transfer robot 340. The transfer robot 340, which operates in a non-contact manner, travels along the track 330 using a non-contact driving mechanism, such as a magnetic levitation and propulsion mechanism. Referring to FIGS. 4A and 4B, the transfer robot 340 includes a pickup unit 342 that supplies power through a power supply cable 332 of the track 330, a moving body 344 mounted on the pickup unit 342, and a regulator 346 disposed on the moving body 344. The pickup unit 342 delivers the current induced from the power supply cable 332 to the regulator 346. The regulator 346 outputs a voltage required for operation of the transfer robot 340 to a controller of the transfer robot 340 using the current supplied from the pickup unit 342.

Referring to FIG. 4, the stacked substrate 410 and the base plate 326 are disposed below the track 330. Although not shown in FIG. 4, the three-phase power supply 460 shown in FIG. 3A may be connected to the stacked substrate 410. Dielectrophoretic force and electrostatic force are generated by the three-phase alternating current voltage applied to the stacked substrate 410. The particles PC may be moved to the first through-holes H1 and the second through-holes H2 by the dielectrophoretic force and the electrostatic force.

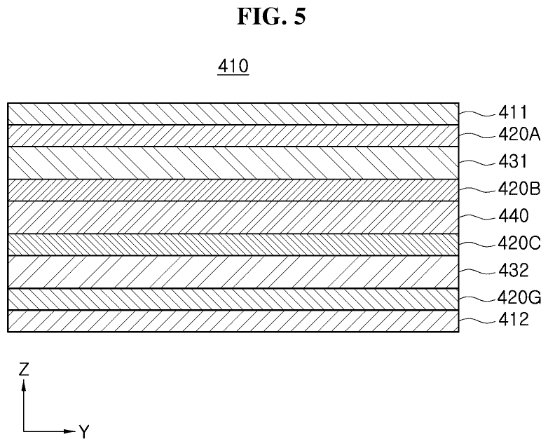

FIGS. 5 and 6 show an example of the cross-section of the stacked substrate 410 having multiple electrode layers. FIGS. 5 and 6 show an example of the cross-section of the stacked substrate 410 having a single ground electrode layer 420G. FIG. 7 shows an example of the cross-section of the stacked substrate 410 in which ground electrodes 451 and 452 are embedded together with the ground electrode layer 420G.

Referring to FIG. 5, the stacked substrate 410 includes a first coating layer 411, a first electrode layer 420A, a first adhesive layer 431, a second electrode layer 420B, an inner layer material 440, a third electrode layer 420C, a second adhesive layer 432, a ground electrode layer 420G, and a second coating layer 412. The stacked substrate 410 may be a printed circuit board.

The first coating layer 411 and the second coating layer 412 define an upper surface and a lower surface of the stacked substrate 410, respectively. The first coating layer 411 and the second coating layer 412 may be formed of an insulating material.

The first electrode layer 420A, the second electrode layer 420B, and the third electrode layer 420C define spaces in which three-phase electrodes connected to the three-phase power supply 460 or three-phase ground electrodes connected to a ground are disposed. In the first electrode layer 420A, the second electrode layer 420B, and the third electrode layer 420C, the three-phase electrodes EA, EB, and EC and the ground electrodes EG are disposed to be spaced apart from each other in the horizontal direction X or Y. Voids (air layers) may be defined between the three-phase electrodes EA, EB, and EC and the ground electrodes EG. Alternatively, in the first electrode layer 420A, the second electrode layer 420B, and the third electrode layer 420C, the adhesive layers 431 and 432 or the inner layer material 440 may extend to fill the voids between the three-phase electrodes EA, EB, and EC and the ground electrodes EG.

The three-phase electrodes EA, EB, and EC having different phases may be disposed in different orders in the first electrode layer 420A, the second electrode layer 420B, and the third electrode layer 420C. For example, as shown in FIG. 6, at a first horizontal position X1 in the vertical direction Z, the first three-phase electrode EA is disposed in the first electrode layer 420A, the second three-phase electrode EB is disposed in the second electrode layer 420B, and the third three-phase electrode EC is disposed in the third electrode layer 420C. The first three-phase electrode EA is electrically connected to the first three-phase power supply 460A. The second three-phase electrode EB is electrically connected to the second three-phase power supply 460B. The third three-phase electrode EC is electrically connected to the third three-phase power supply 460C. The three-phase electrodes EA, EB, and EC and the ground electrodes EG may be formed as wires. Alternatively, the three-phase electrodes EA, EB, and EC and the ground electrodes EG may be formed within the stacked substrate 410 through a patterning process.

In the first electrode layer 420A, the three-phase electrodes EA, EB, and EC, which are connected to the three-phase power supply 460, and the ground electrodes EG, which are connected to the ground, may be alternately arranged in the first horizontal direction X. Similarly, in the second electrode layer 420B and the third electrode layer 420C, the three-phase electrodes EA, EB, and EC, which are connected to the three-phase power supply 460, and the ground electrodes EG, which are connected to the ground, may be alternately arranged in the first horizontal direction X. Referring to FIG. 6, the three-phase electrodes EA, EB, and EC are alternately arranged in the first horizontal direction X, which is the traveling direction of the transfer robot 340. In the first electrode layer 420A, the second electrode layer 420B, and the third electrode layer 420C, the first three-phase electrode EA, the second three-phase electrode EB, and the third three-phase electrode EC are alternately arranged at regular intervals in the first horizontal direction X.

In another embodiment, in the first electrode layer 420A, the second electrode layer 420B, and the third electrode layer 420C, the three-phase electrodes EA, EB, and EC, which are connected to the three-phase power supply 460, and the ground electrodes EG, which are connected to the ground, may be alternately arranged in the second horizontal direction Y, which is perpendicular to the first horizontal direction X corresponding to the traveling direction of the transfer robot 340.

At a first horizontal position X1, the first three-phase electrode EA connected to the first three-phase power supply 460A may be disposed on the first electrode layer 420A, the second three-phase electrode EB connected to the second three-phase power supply 460B may be disposed on the second electrode layer 420B, and the third three-phase electrode EC connected to the third three-phase power supply 460C may be disposed on the third electrode layer 420C. At a second horizontal position X2, the ground electrodes EG may be disposed on the first electrode layer 420A, the second electrode layer 420B, and the third electrode layer 420C. At a third horizontal position X3, the second three-phase electrode EB may be disposed on the first electrode layer 420A, the third three-phase electrode EC may be disposed on the second electrode layer 420B, and the first three-phase electrode EA may be disposed on the third electrode layer 420C. At a fourth horizontal position X4, the ground electrodes EG may be disposed on the first electrode layer 420A, the second electrode layer 420B, and the third electrode layer 420C. At a fifth horizontal position X5, the third three-phase electrode EC may be disposed on the first electrode layer 420A, the first three-phase electrode EA may be disposed on the second electrode layer 420B, and the second three-phase electrode EB may be disposed on the third electrode layer 420C.

The ground electrode layer 420G provides a space in which the ground electrodes connected to the ground are disposed. The ground electrode layer 420G may correspond to a single ground plate made of metal. Alternatively, in the ground electrode layer 420G, the ground electrodes may be disposed to be spaced apart from each other at regular intervals in the horizontal direction X or Y. Voids (air layers) may be defined between the ground electrodes in the ground electrode layer 420G. Alternatively, in the ground electrode layer 420G, the second adhesive layer 432 may extend to fill the voids between the ground electrodes.

The first adhesive layer 431 and the second adhesive layer 432 may be made of a prepreg (pre-impregnated) material. For example, the first adhesive layer 431 and the second adhesive layer 432 may be made of an epoxy resin.

The inner layer material 440 is formed in the central portion of the stacked substrate 410. The inner layer material 440 may include conductive layers to electrically connect various electrodes to each other. In addition, the inner layer material 440 may include an insulating layer to block electrical interference between the conductive layers or between the second electrode layer 420B and the third electrode layer 420C adjacent to the conductive layers.

Referring to FIG. 7, in the stacked substrate 410 shown in FIG. 5, a first ground electrode 451 may be embedded in the first adhesive layer 431, and a second ground electrode 452 may be embedded in the second adhesive layer 432. As shown in FIG. 7, because the ground electrodes 451 and 452 are additionally embedded at positions adjacent to the first electrode layer 420A and the second electrode layer 420B, stronger dielectrophoretic force and electrostatic force may be generated.

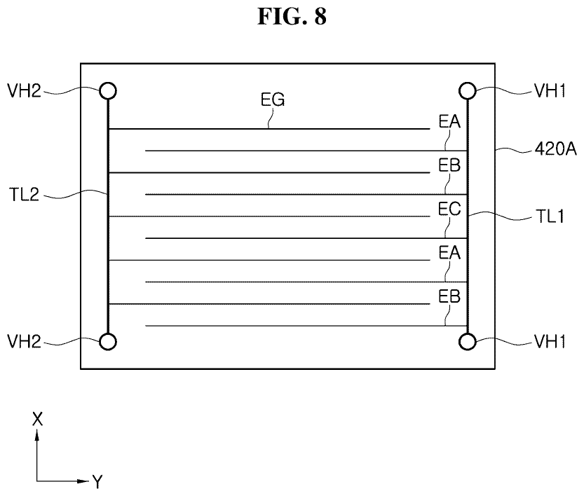

FIG. 8 shows an example of a wiring structure in an electrode layer of the stacked substrate 410. FIG. 8 shows a wiring structure in the first electrode layer 420A in an X-Y plane, as viewed from above. Referring to FIG. 8, in the first electrode layer 420A, the ground electrodes EG and the three-phase electrodes EA, EB, and EC are alternately arranged. The first three-phase electrode EA, the second three-phase electrode EB, and the third three-phase electrode EC are sequentially and alternately arranged in the first horizontal direction X. The first three-phase electrode EA, the second three-phase electrode EB, and the third three-phase electrode EC may be electrically connected to the first three-phase power supply 460A, the second three-phase power supply 460B, and the third three-phase power supply 460C, respectively, through a common three-phase electrode line TL1 and via holes VH1 for three-phase electrode connection. The ground electrodes EG may be connected to the ground through a common ground electrode line TL2 and via holes VH2 for ground electrode connection.

Similarly, in the second electrode layer 420B and the third electrode layer 420C, the ground electrodes EG and the three-phase electrodes EA, EB, and EC may be alternately arranged. In the second electrode layer 420B and the third electrode layer 420C, the first three-phase electrode EA, the second three-phase electrode EB, and the third three-phase electrode EC may be sequentially and alternately arranged in the first horizontal direction X. The via holes VH1 and VH2 may be commonly formed in the first electrode layer 420A, the second electrode layer 420B, and the third electrode layer 420C, and electrical connection to the three-phase electrodes EA, EB, and EC and the ground electrodes EG may be achieved through the via holes VH1 and VH2.

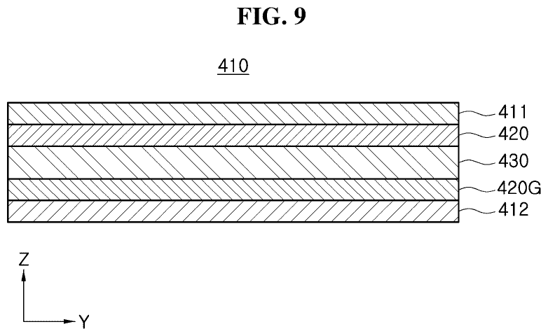

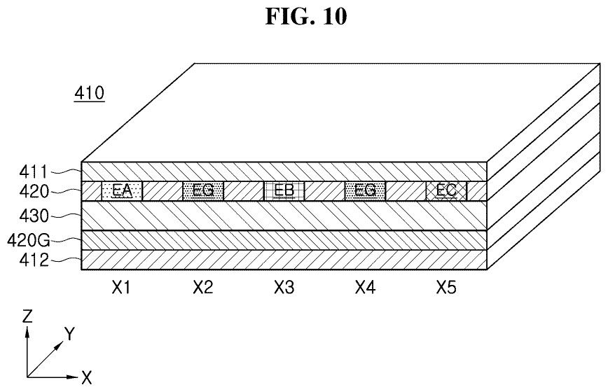

FIGS. 9 and 10 show another example of a stacked substrate having a single electrode layer. FIGS. 5 to 7 show an example in which multiple electrode layers are stacked in the vertical direction Z and the three-phase electrodes EA, EB, and EC are disposed to be spaced apart from each other in the first horizontal direction X in each electrode layer. FIGS. 9 and 10 show the structure of a stacked substrate 410 in which the three-phase electrodes EA, EB, and EC are disposed to be spaced apart from each other in the first horizontal direction X in a single electrode layer.

Referring to FIGS. 9 and 10, the stacked substrate 410 may include a first coating layer 411, an electrode layer 420, an insulating layer 430, a ground electrode layer 420G, and a second coating layer 412. The first coating layer 411 is disposed at the uppermost position, the electrode layer 420 is disposed under the first coating layer 411, the insulating layer 430 is disposed under the electrode layer 420, the ground electrode layer 420G is disposed under the insulating layer 430, and the second coating layer 412 is disposed under the ground electrode layer 420G.

Compared to the structure shown in FIGS. 5 and 6, the stacked substrate 410 shown in FIGS. 9 and 10 is structured such that a single electrode layer 420 is provided and the three-phase electrodes EA, EB, and EC and the ground electrodes EG are alternately disposed in the first horizontal direction X in the electrode layer 420. The first three-phase electrode EA, the second three-phase electrode EB, and the third three-phase electrode EC may be sequentially and alternately arranged in the first horizontal direction X in the electrode layer 420. The three-phase electrodes EA, EB, and EC and the ground electrodes EG may also be alternately arranged in the second horizontal direction Y.

The particle collection device 400 described above with reference to FIGS. 1 to 10 is configured to move particles PC present in the transfer module 30 to the through-holes H1 and H2, thereby discharging the particles PC.

The particles PC are removed by placing the three-phase electrodes EA, EB, and EC in the stacked substrate 410 and applying sinusoidal voltage waveforms from the three-phase power supply 460 to the three-phase electrodes EA, EB, and EC. The particle collection device 400 functions as a type of electrostatic precipitator that collects the particles PC to a desired outlet. Generation of driving force for moving the particles PC is analogous to generation of a rotating magnetic field in a motor.

The particle collection device 400 separates and discharges particles PC present in the semiconductor manufacturing equipment 1 using a traveling electric field, dielectrophoresis, and Coulomb electrostatic force. Through the particle collection device 400, fine particles may be effectively removed with a compact installation space and reduced cost.

The dielectrophoretic force acting on a dielectric microparticle in a fluid is determined by the electric field applied to the periphery of the particle, the permittivity and size of the particle, and the permittivity of the fluid. On the other hand, drag force is determined by the viscosity of the fluid, the size of the particle, and the relative velocity between the fluid and the particle. Accordingly, if the temperature of the system and the size of the particle remain constant, the dielectrophoretic force and the drag force may be independently calculated, and the resultant force may be obtained based on the principle of superposition.

Force \vec{F} that causes motion of the particle is calculated based on Newton's equation of motion, as shown in Equation 1 below. In Equation 1, \vec{F}_{DEP} represents dielectrophoretic force, \vec{F}_{D} represents drag force, \vec{F}_{G} represents gravitational force, \vec{F}_{coulomb} represents electrostatic force, m represents the mass of the particle PC, t represents time, and v represents the velocity of the particle PC.

$$\vec{F} = {\vec{F}}_{DEP} + {\vec{F}}_{D} + {\vec{F}}_{G} + {\vec{F}}_{Coulomb} = mdv / dt \qquad [ Equation 1 ]$$

The dielectrophoretic force \vec{F}_{DEP} and the electrostatic force \vec{F}_{coulomb} based on the permittivity of a 10 μm particle at a specific position are determined as shown in Equation 2 and Equation 3, respectively.

$${\vec{F}}_{DEP} = 2 π {ε}_{f} {R}^{3} \frac{{ε}_{p} - {ε}_{f}}{{ε}_{p} + 2 {ε}_{f}} ∇ {E}^{2} \qquad [ Equation 2 ]$$

$${\vec{F}}_{coulomb} = q \vec{E} \qquad [ Equation 3 ]$$

In Equations 2 and 3, R represents the radius of the particle, E represents the applied electric field, q represents the amount of charge of the particle, εₚ represents the permittivity of the particle, and ε_{f} represents the permittivity of the fluid.

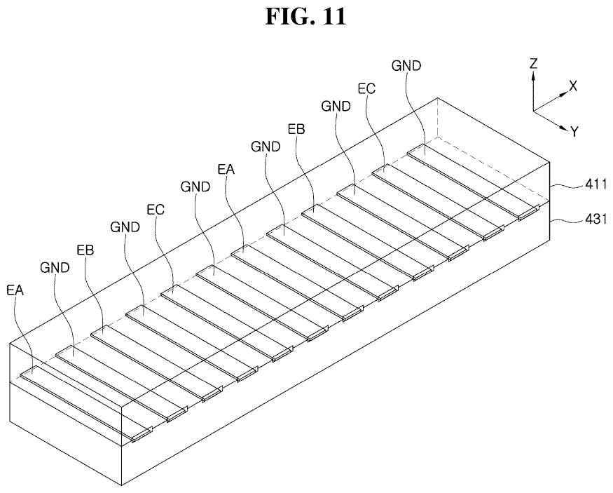

FIG. 11 shows a case in which the three-phase electrodes EA, EB, and EC are alternately arranged in the traveling direction of the transfer robot 340. Referring to FIG. 11, the three-phase electrodes EA, EB, and EC and the ground electrodes EG are alternately disposed in the first horizontal direction X between the first coating layer 411 and the first adhesive layer 431. The first three-phase electrode EA, the second three-phase electrode EB, and the third three-phase electrode EC may be sequentially and alternately arranged in the first horizontal direction X. A time-varying electric field may be generated by the three-phase sinusoidal voltage applied to the three-phase electrodes EA, EB, and EC disposed in the first horizontal direction X, and the particles PC may be moved to the outlet by a magnetic field formed by the time-varying electric field.

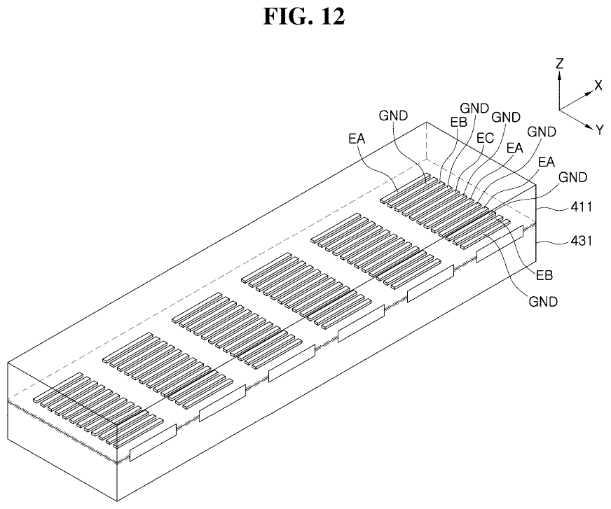

FIG. 12 shows a case in which the three-phase electrodes are alternately arranged in a direction perpendicular to the traveling direction of the transfer robot. Referring to FIG. 12, the three-phase electrodes EA, EB, and EC and the ground electrodes EG are alternately disposed in the second horizontal direction Y between the first coating layer 411 and the first adhesive layer 431. The first three-phase electrode EA, the second three-phase electrode EB, and the third three-phase electrode EC may be sequentially and alternately arranged in the second horizontal direction Y. A time-varying electric field may be generated by the three-phase sinusoidal voltage applied to the three-phase electrodes EA, EB, and EC disposed in the second horizontal direction Y, and the particles PC may be moved to the outlet by a magnetic field formed by the time-varying electric field.

As is apparent from the above description, according to the present disclosure, by supplying three-phase power to three-phase electrodes disposed in the stacked substrate, very fine particles present on a wall surface or a bottom surface may be effectively discharged by dielectrophoretic force and electrostatic force.

Although the preferred embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the accompanying claims, and all technical ideas within the scope of equivalents to the claims should be construed as falling within the scope of the disclosure.

What is claimed is:

1. A transfer module configured to transfer a substrate in semiconductor manufacturing equipment, the transfer module comprising:
a frame body;
a track disposed on the frame body;
a transfer robot configured to travel along the track; and
a particle collection device provided in the frame body,
wherein the particle collection device comprises:
a stacked substrate having three-phase electrodes disposed therein, the three-phase electrodes being spaced apart from each other in a horizontal direction and a vertical direction; and
a three-phase power supply configured to supply three-phase power to the three-phase electrodes.

2. The transfer module as claimed in claim 1, wherein the frame body comprises:
a column supporting a lower portion of the track;
a base frame supporting a lower portion of the column; and
a base plate mounted at a central portion of the base frame, the base plate comprising a plurality of first through-holes connected to an exhaust fan configured to generate a negative pressure.

3. The transfer module as claimed in claim 2, wherein the stacked substrate is disposed on the base plate and comprises a plurality of second through-holes formed in alignment with the plurality of first through-holes.

4. The transfer module as claimed in claim 1, wherein the three-phase power supply comprises:
a first phase power supply configured to apply a first phase sinusoidal voltage to a first phase electrode among the three-phase electrodes;
a second phase power supply configured to apply a second phase sinusoidal voltage, having a phase difference of 120 degrees from the first phase sinusoidal voltage, to a second phase electrode among the three-phase electrodes; and
a third phase power supply configured to apply a third phase sinusoidal voltage, having a phase difference of −120 degrees from the first phase sinusoidal voltage, to a third phase electrode among the three-phase electrodes.

5. The transfer module as claimed in claim 1, wherein the stacked substrate comprises:
a first coating layer;
a first electrode layer disposed under the first coating layer and electrically connected to the three-phase power supply;
a first adhesive layer disposed under the first electrode layer;
a second electrode layer disposed under the first adhesive layer and electrically connected to the three-phase power supply;
an inner layer material disposed under the second electrode layer;
a third electrode layer disposed under the inner layer material and electrically connected to the three-phase power supply;
a second adhesive layer disposed under the third electrode layer;
a ground electrode layer disposed under the second adhesive layer; and
a second coating layer disposed under the ground electrode layer.

6. The transfer module as claimed in claim 5, wherein the stacked substrate further comprises:
a first ground electrode embedded in the first adhesive layer; and
a second ground electrode embedded in the inner layer material.

7. The transfer module as claimed in claim 5, wherein the first electrode layer has three-phase electrodes and ground electrodes alternately arranged therein in a horizontal direction, the three-phase electrodes being connected to the three-phase power supply, the ground electrodes being connected to a ground.

8. The transfer module as claimed in claim 7, wherein, in the first electrode layer, the three-phase electrodes comprise a first three-phase electrode, a second three-phase electrode, and a third three-phase electrode arranged at regular intervals, with the ground electrodes interposed therebetween.

9. The transfer module as claimed in claim 7, wherein the three-phase electrodes are alternately arranged in a first horizontal direction, the first horizontal direction being a traveling direction of the transfer robot.

10. The transfer module as claimed in claim 7, wherein the three-phase electrodes are alternately arranged in a second horizontal direction perpendicular to a first horizontal direction, the first horizontal direction being a traveling direction of the transfer robot.

11. A transfer module configured to transfer a substrate in semiconductor manufacturing equipment, the transfer module comprising:
a frame body;
a track disposed on the frame body;
a transfer robot configured to travel along the track; and
a particle collection device provided in the frame body,
wherein the particle collection device comprises:
a stacked substrate having three-phase electrodes disposed therein, the three-phase electrodes being spaced apart from each other in a horizontal direction; and
a three-phase power supply configured to supply three-phase power to the three-phase electrodes.

12. The transfer module as claimed in claim 11, wherein the frame body comprises:
a column supporting a lower portion of the track;
a base frame supporting a lower portion of the column; and
a base plate mounted at a central portion of the base frame, the base plate comprising a plurality of first through-holes connected to an exhaust fan configured to generate a negative pressure.

13. The transfer module as claimed in claim 12, wherein the stacked substrate is disposed on the base plate and comprises a plurality of second through-holes formed in alignment with the plurality of first through-holes.

14. The transfer module as claimed in claim 11, wherein the three-phase power supply comprises:
a first phase power supply configured to apply a first phase sinusoidal voltage;
a second phase power supply configured to apply a second phase sinusoidal voltage having a phase difference of 120 degrees from the first phase sinusoidal voltage; and
a third phase power supply configured to apply a third phase sinusoidal voltage having a phase difference of −120 degrees from the first phase sinusoidal voltage.

15. The transfer module as claimed in claim 11, wherein the stacked substrate comprises:
a first coating layer;
an electrode layer disposed under the first coating layer;
an insulating layer disposed under the electrode layer;
a ground electrode layer disposed under the insulating layer; and
a second coating layer disposed under the ground electrode layer.

16. The transfer module as claimed in claim 15, wherein the electrode layer has three-phase electrodes and ground electrodes alternately arranged therein in a horizontal direction, the three-phase electrodes being connected to the three-phase power supply, the ground electrodes being connected to a ground.

17. The transfer module as claimed in claim 16, wherein, in the electrode layer, the three-phase electrodes comprise a first three-phase electrode, a second three-phase electrode, and a third three-phase electrode arranged at regular intervals, with the ground electrodes interposed therebetween.

18. The transfer module as claimed in claim 17, wherein the three-phase electrodes are alternately arranged in a first horizontal direction, the first horizontal direction being a traveling direction of the transfer robot.

19. The transfer module as claimed in claim 17, wherein the three-phase electrodes are alternately arranged in a second horizontal direction perpendicular to a first horizontal direction, the first horizontal direction being a traveling direction of the transfer robot.

20. Semiconductor manufacturing equipment comprising:
a load port module comprising a placing table configured to allow a cassette accommodating a substrate to be placed thereon;
an index module comprising an index robot configured to transfer the substrate with respect to the cassette;
a transfer module configured to receive the substrate from the index module and to transfer the substrate to one or more process chambers configured to perform processing on the substrate; and
a processing module having the one or more process chambers arranged therein,
wherein the transfer module comprises:
a frame body;
a track disposed on the frame body;
a transfer robot configured to travel along the track; and
a particle collection device provided in the frame body,
wherein the particle collection device comprises:
a stacked substrate having three-phase electrodes disposed therein, the three-phase electrodes being spaced apart from each other in a vertical direction and a horizontal direction; and
a three-phase power supply configured to supply three-phase power to the three-phase electrodes,
wherein the frame body comprises:
a column supporting a lower portion of the track;
a base frame supporting a lower portion of the column; and
a base plate mounted at a central portion of the base frame, the base plate comprising a plurality of first through-holes connected to an exhaust fan configured to generate a negative pressure,
wherein the stacked substrate is disposed on the base plate and comprises a plurality of second through-holes formed in alignment with the plurality of first through-holes,
wherein the stacked substrate comprises:
a first coating layer;
a first electrode layer disposed under the first coating layer and electrically connected to the three-phase power supply;
a first adhesive layer disposed under the first electrode layer;
a second electrode layer disposed under the first adhesive layer and electrically connected to the three-phase power supply;
an inner layer material disposed under the second electrode layer;
a third electrode layer disposed under the inner layer material and electrically connected to the three-phase power supply;
a second adhesive layer disposed under the third electrode layer;
a ground electrode layer disposed under the second adhesive layer; and
a second coating layer disposed under the ground electrode layer,
wherein the first electrode layer has three-phase electrodes and ground electrodes alternately arranged therein in a horizontal direction, the three-phase electrodes being connected to the three-phase power supply, the ground electrodes being connected to a ground,
wherein, in the first electrode layer, the three-phase electrodes comprise a first three-phase electrode, a second three-phase electrode, and a third three-phase electrode arranged at regular intervals, with the ground electrodes interposed therebetween, and
wherein the three-phase electrodes are arranged in a first horizontal direction or in a second horizontal direction perpendicular to the first horizontal direction, the first horizontal direction being a traveling direction of the transfer robot.
